(19) United States
(12) Patent Application Publication
(10) Pub. No.: US 2017/0050377 A1
(43) Pub. Date: Feb. 23, 2017

(54) Laser Diode Array Based Photopolymer Exposure System

(71) Applicant: Daniel Gelbart, Vancouver (CA)

(72) Inventor: Daniel Gelbart, Vancouver (CA)

(21) Appl. No.: 14/832,911

(22) Filed: Aug. 21, 2015

(51) Int. Cl. B29C 67/00; H01S 5/00; H01S 5/40

(52) U.S. Cl. CPC B29C 67/0085; H01S 5/4025; H01S 5/005; B29C 67/0066; B29C 67/0077; B33Y 30/00

(57) ABSTRACT

The invention uses a scanned two dimensional array of single mode laser diodes to generate a large number of beams scanning a large area of liquid photopolymer. The optical design is further simplified by using interleaved scanning generated by tilring a glass plate. Using a wavelength of 405-410nm allows the use of low cost laser diodes and a simplified optical design.

### FIELD OF THE INVENTION

The invention is mainly in the field of 3D printing, and specifically for stereolithography.

### BACKGROUND OF THE INVENTION

Stereolitography, also known as SLA, is a well known method of additive manufacturing or 3D printing. For full description see : http://en.wikipedia.org/wiki/Stereolithography One of the limiting factors in this process is the amount of light, particularly blue or UV light, that can be supplied to cure the photopolymer. High power UV lasers are expensive, while low cost laser diodes have low power and it is difficult to arrange a large number of them to generate closely spaced tracks. One object of the invention is to combine a large number of relatively low power diodes to achieve a high power delivered at a high resolution and large number of tracks. It is also desirable to scan a large area of liquid photopolymer without moving the liquid photopolymer, and preferably without moving the laser source. Prior art used deformable mirror devices as light modulators and also used several laser diodes to increase speed. If diodes are used in a linear array there is a limit to the number of diodes that can be used without increasing the array size to an unpractical length. Since many of the liquid photoresists used respond to exposure at the 400-420 nm range it is advantageous to operate the system using laser diodes and collimating lenses used by the DVD industry. Laser diodes used in R/W DVD players operate at 405-410 nm and are available up to 200 mW of power.

### SUMMARY OF THE INVENTION

The invention uses a scanned two dimensional array of single mode laser diodes to generate a large number of beams scanning a large area of liquid photopolymer. The optical design is further simplified by using interleaved scanning generated by tilting a glass plate. Using a wavelength of 405-410 nm allows the use of low cost laser diodes and a simplified optical design.

### BRIEF DESCRIPTION OF THE DRAWINGS

FIG. 1 is a general view of the scanning system part of a 3D printer based on stereolithography.

FIG. 2 is a plan view of the laser diode array, showing the principle of reducing the apparent pitch.

FIG. 3 is a cross-section of the laser diode array showing the adjustment method.

FIG. 4 is a side view of the scanning system using low magnification ratio and interleaved writing.

FIG. 5 is a depiction of the writing beams on the PCB illustrating the principle of interleaved writing.

FIG. 6 is a side view of the scanning system using high reduction ratio optics and non- interleaved writing.

FIG. 7 is a depiction of the writing beams on the PCB illustrating the principle of non-interleaved writing.

FIG. 8 is a side view of part of the scanning system showing the use of a rotating polygon for scanning

FIG. 9 is a side view of part of the scanning system showing the use of an oscillating lens for scanning

FIG. 10 is a view of the method used to convert the laser diode beam from having an elliptical cross section to a round cross section.

### DESCRIPTION OF THE PREFERRED EMBODIMENT

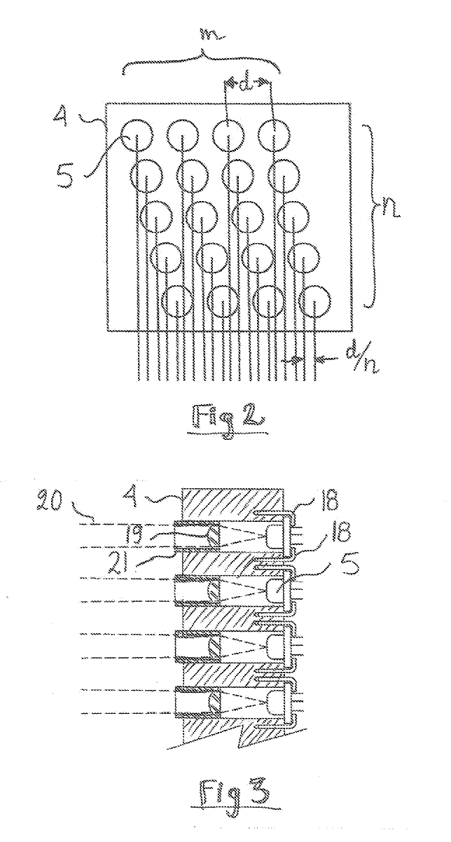

In order to make an efficient use of the optical field-of-view of the scanning system, a two dimensional array of single mode laser diodes is used as a multi-beam source for image-wise exposing the surface of the liquid photopolymer. The principle of such an array is disclosed in U.S. Pat. No. 4,743,091, hereby incorporated by reference. The principle is also shown in FIG. 2. An array 4 has a 2D array of laser diodes 5. Since each row is shifted relative to the previous one, an array having m columns and n rows will create m×n equally spaced lines when scanned. Furthermore, if the pitch of the laser diodes is d the line spacing will be d/n. This reduces the need for a strong optical image reduction as the actual pitch of the lines in stereolithographe is in typically in the range of 25 um to 250 um. The best utilization of the optics is when m=n, however other ratios can be chosen to maximize throughput. An illustrative example will be described for a system having a resolution of 50 um, i.e. The distance between the exposed lines is 50 um. Typically the scanning optical spot is made larger than the resolution, to achieve smooth line edges. Since the throughput of most stereolithography systems is exposure energy limited, the resolution can often be increased without affecting speed. The resolution and scanned area size can easily be changed by changing the imaging lens, or even continuously changed by using a zoom lens. Maximum throughtput is achieved when scan area matches the size of the printed object. By the way of example, m=60 diodes and n=20 diodes. Since all beams of all diodes have to point to the same spot, the imaging lens location, and have to come to a sharp focus on the surface of the photopolymer, two adjustments are needed. This is shown in FIG. 3. The manufacturing tolerances of standard laser diodes are not sufficiently good to eliminate adjustments. The laser diodes, typically housed in a 5.6 mm or 3.8 mm diameter package, are clamped to the array block 4 using bent spring steel wires 18. Clearly other clamping methods, such as small screws, can be used. This allows the lateral sliding of the diode to make beam 20 point to the desired point. Typically the adjustment range needed is below 0.5 mm. Collimating lens 19 is mounted in metal tube 21. The tube can be moved in and out in array block 4 to achieve the desired degree of collimation in beam 20. Tube 21 can be threaded or rely on friction to retain position. Lens 19 is typically a single element molded glass aspheric. In the preferred embodiment both lens 19 and diode 5 are the same type as used in R/W DVD players, typically operating at 405-410 nm. This allows the construction of a very low cost array. Many stereolithography machines operate in the UV, typically 365 nm, as photopolymers lose some sensitivity at 405 nm compared to UV, however working at 405-410 nm has major advantages:

a. Laser power is significantly cheaper at 405 nm compared to 365 nm, so the sensitivity loss can be compensated by more power.

b. Optics are much lower cost at 405 nm compared to 365 nm as regular glasses can be used, no need to use fused silica optics.

c. High power UV light is a health hazard.

d. Intense UV light lowers the reliability of optical systems.

In general, the price of laser diodes goes up rapidly when wavelength goes below 400 nm. On the other hand, wavelength above 410 nm require tighter filtering of the “yellow light” in shops to remove any blue light. This places the desired operating range at 400-410 nm. For UV the desired operating range is 360-370 nm.

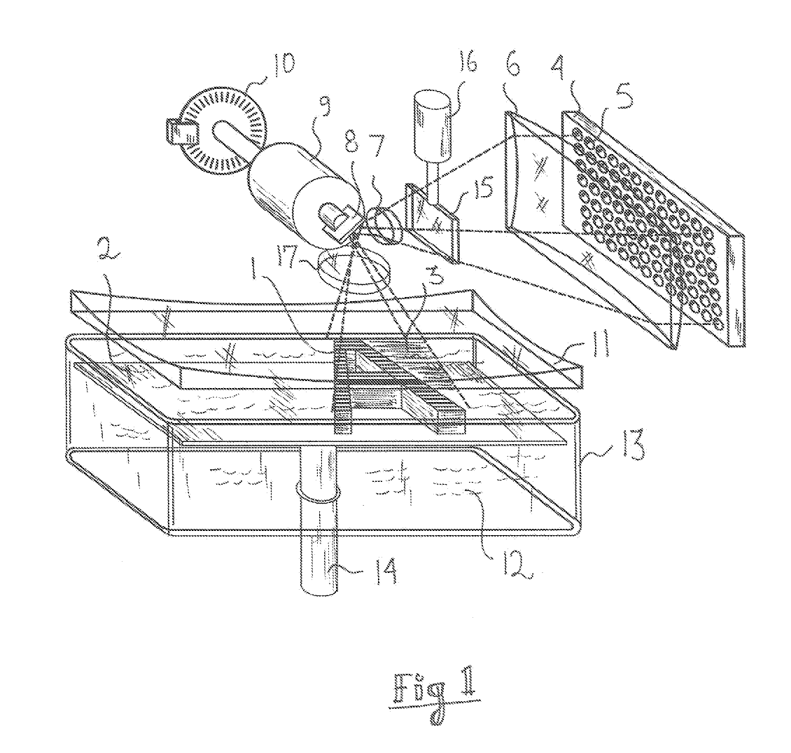

Referring now to FIG. 1, laser diodes 5 of array 4 are pointing at imaging lens 7. It is desired to add a field flattening lens 6 to keep beams parallel as they emerge from array. An oscillating mirror 8 is located next to lens 7, to minimize the required mirror size. Mirror 8 can be moved by an electric motor such as a stepper motor 9 and its position is measured by shaft encoder 10 to a high degree of accuracy. It can also be mounted on a galvanometer type actuator. Such scanners are commercially available. The scanner converts the point images of laser diodes 5 into scan lines 3. Clearly the diodes are modulated by the image data. By the way of example, the size of mirror 8 is about 5×10 mm. Imaging lens 7 is selected to create an image of array 4 on the surface of photopolymer 12 held in tank 13. Object 1 is being built layer by layer by lowering build platform 2 after each layer is exposed and ploymerized. Lens 11 is an optional field flattening lens. Lens 17 can be used instead of lens 7 as an imaging lens or the optical power can be divided between lens 17 and lens 7. When lens 17 is used it needs to be of the f-theta type. The active aperture of lens 7 or lens 17 is determined as a trade-off between resolution and depth of focus. In the preferred embodiment the distance between lens 7 and photopolymer 12 is about 800 mm. The distance between lens 7 and array 4 is selected to achieve the desired line spacing of scan lines 3. The trade-off determining the diameter of lens 7 is done as following: the spot size the lens will form on the photopolymer is about 1.2(f/#)wavelength. Since the desired spot diameter is about 100 um for 50 um resolution, the f/# of lens 7 is about f/200. For a distance of 800 mm and an f/200 lens the active aperture of lens 7 is only about 4 mm. The depth of focus is about 3(f/#)²wavelength, giving about 50 mm. As the formulas show, increasing the lens diameter will increase resolution but decrease depth of focus. Field flattener lens 11 is of low optical power and does not significantly alter this approximate calculation. Sometimes an additional optical component, known as an “optical isolator” needs to be added in order to prevent light reflections into the laser diodes. Such reflections may cause power fluctuations. The optical isolator plus other components required to drive laser diodes are not detailed in this disclosure as they are well known in the art of laser diodes.

In an illustrative embodiment the size of the scanned area is 450×800 mm. The scanning is done in the 800 mm direction. In order to perform the full scanning without moving the photopolymer or the array, ideally a scan of 9000 lines is required (450 mm/50 um). Since the array has 1200 diodes, generating 1200 scan lines, overscanning and interleaving is required. With 8 fold interleaving 9600 scan lines can be generated. The interleaving is explained in more details later on in this disclosure. This can be done by adding an optical image shifting device such as a tilting glass plate 15 rotated by an actuator such as a stepper motor 16. Tilting of the glass shifts the image of the array by a small amount, allowing the writing of several interleaved scans without table movement. For a glass plate of thickness t the approximate image shift will be ⅓ of t times the tilt angle (in radians). By the way of example, if the diodes in the 60×20 array are mounted on 6 mm pitch, the apparent pitch will be 6 mm:20=0.3 mm. Since the required pitch of the lines in a single scan is 8×50 um=0.4 mm, the image of the array actually has to be magnified by a factor of 4/3. To divide the 300 um apparent pitch of the array in the previous example into 8 images, glass will need to shift the image 7/8×300 um=262.5 um. For a 3 mm glass plate the required tilt angle is about 260 mR or about 15 degrees. A regular stepper motor operated in microstepping mode will be sufficiently accurate and fast. Such an arrangement will write a swath of 8×1200 lines=9600 lines or 480 mm wide swath at 50 um resolution by using 8 scans. The advantage of using a tilting glass plate over other methods of image displacement is that the glass is moved relatively large angles making the angular accuracy less demanding and allowing the use of a stepper motor to tilt the glass plate. A stepper motor has a typical accuracy of 0.1 degree, which is about 1/20 of the step required in the illustrative example.

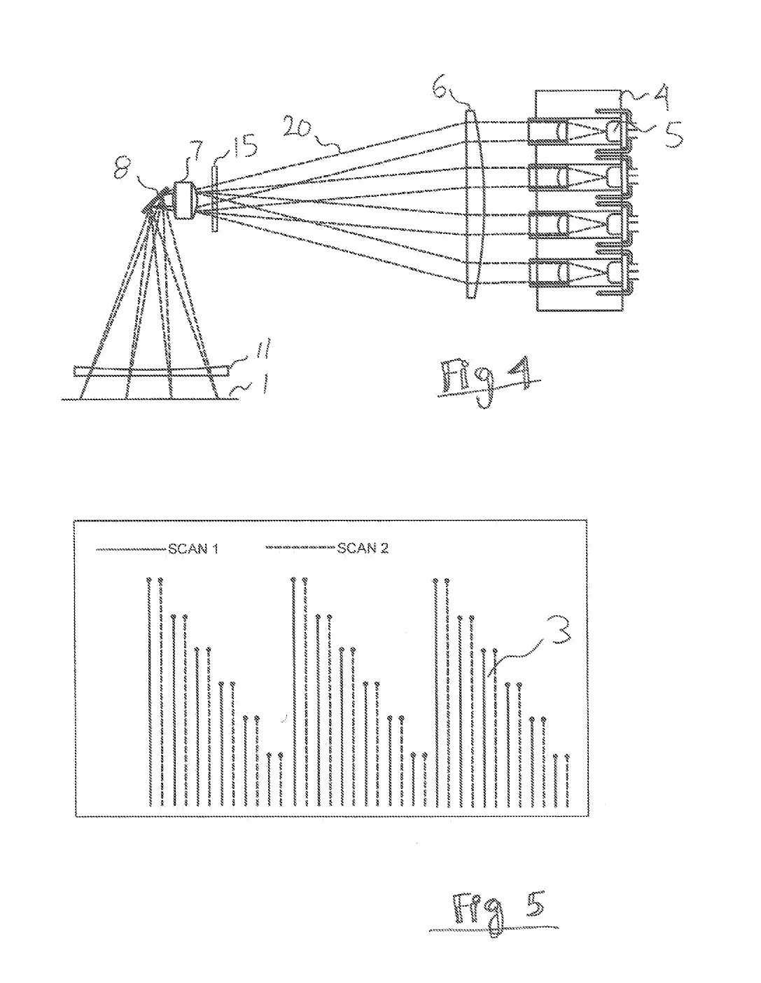

The imaging in this invention can be done in two modes: interleaved and non-interleaved writing. Interleaved writing is used in order to simplify the optical system and to make the system more immune to optical drift. It was covered in the previous example and shown in FIGS. 4 and 5. FIG. 5 shows the apperance of the interleaved scan lines at the writing plane (polymer surface). In FIG. 5 a 2:1 interleave is used.

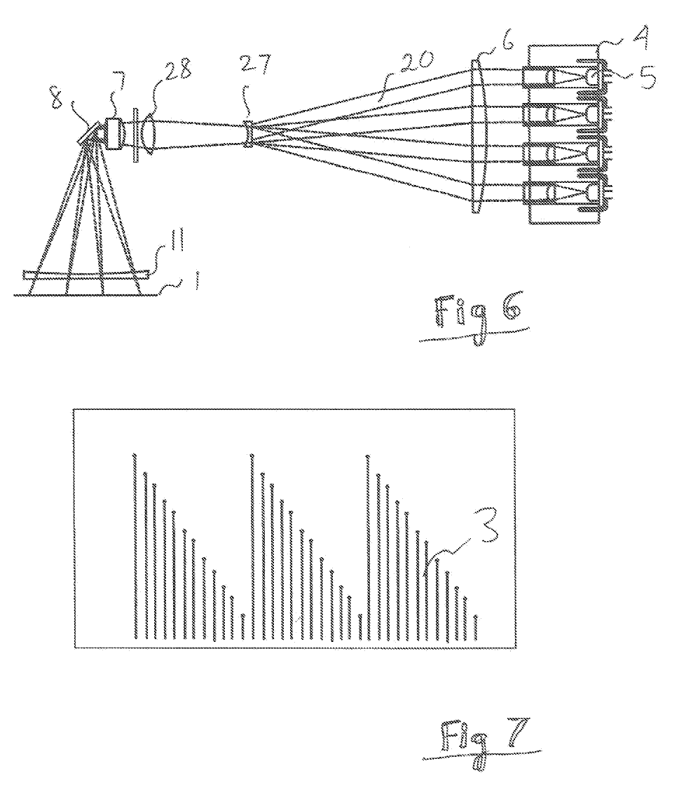

In order to use non-interleaved writing, which maximizes throughput for small objects at the expense of optical complexity, a large de-magnification ratio needs to be used, for example, for the same 300 um aparent pitch and a written pitch of 50 um a de-magnification of 6X is needed. If all the de-magnification is done by lens 7, as shown in FIG. 4, the distance between array 4 and lens 7 needs to be 6×800 mm=4.8 meter, which is inconvenient. A more compact optical design is shown in FIG. 6. A reverse telescope comprising of lenses 27 and 28 is placed between the array 4 and lens 7. If the focal length of lens 28 is f1 and of lens 27 is f2, the power of the telescope is f1/f2 and it will make array 4 seem f1/f2 times further away. Again, the effect of field flattening lenses 6 and 11 is ignored in this simple calculation. With f1=200 mm and f2=25 mm the distance between the array and lens 7 can be reduced 8 fold, from 4.8 meter to 4.8:8=0.6 meter, which is convenient. The resulting scan lines are shown in FIG. 7. In this mode the width of the exposed area is only 1200×50 um=60 mm. To scan the whole area relative movement between scanner and photopolymer will be required. To be able to expose an area of 800×450 mm in one second, using typical photopolymer sensitivity and 50 um layer depth, needs an optical power of about 150W. Not much is gained by faster exposure as there is a delay of about one second between exposures. This delay is mainly due to the time it takes to level the surface of the liquid photopolymer. In systems exposing through the bottom of vat 13 this delay is replaced by other delays, for example filling time of the layer. Adding over-scanning losses at start and end of scan (about 20%), scan mirror duty cycle losses (about 10%) and optical losses (about 10%) brings the laser power required to about 220W. Using 200 mW laser diodes will generate a total power of 0.2W×1200=240W. An example of such diodes, used in R/W DVD players, are SLD3237YF made by Sony and NDV4542 made by Nichia, both from Japan. For lower speed the more economical 100 mW laser diodes can be used. All these diodes operate at a wavelength of 405-410 nm. The data rate is not a limit in a 3D printer. In the example given, the total number of bits per layer is 800×450×20×20=144 Mbit, which works out to 144 Mbit/1200 diodes=120 Kbit/sec per diode. The scanning rates are also not a limiting factor. In the illustrative example given, using 8 time interleaving, scanning mirror 8 and tilting glass 15 only needs to move 8 times per second, well within the capability of a stepper motor.

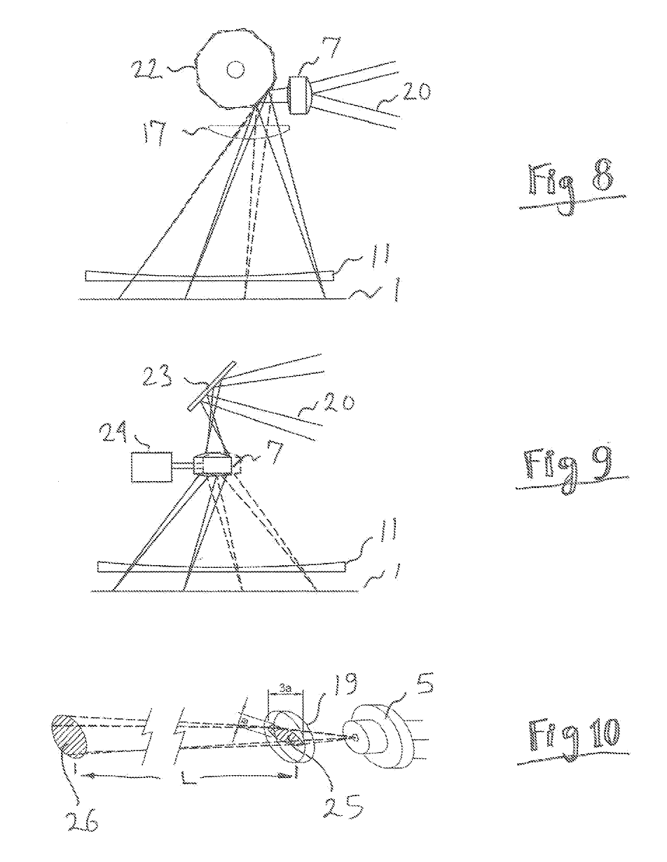

Alternate scanning systems are shown in FIGS. 8 and 9. FIG. 8 uses a rotating optical polygon 22, with or without an f-theta lens 17. FIG. 9 shows scanning by moving the imaging lens. If a reduced image of the array is formed in front of imaging lens 7, and a short focal length is chosen for lens 7, small lateral displacements of lens 7 will cause a large scan. Lens 7 is moved by actuator 24. Mirror 23 is a fixed mirror. Other scanning methods that can be used are acousto-optical deflectors, preferable of the slow shear mode, and a rotating transparent polygon in front of lens 7.

Laser diodes typically generate an beam having an oval rather than round cross section. This can lead to generate an oval exsposure spot on the photopolymer, which is not desirable. A common solution is to add anamorphic optics to each laser diode, which is a large expense because of the large number of laser diodes used. Because the array has to be at a large distance from the imaging lens, to achieve the right reduction ratio, a different solution is shown in FIG. 10. This solution will also work when the actual distance is not large but is made to look large using an inverse telescope, as explained earlier. The solution takes advantage of the fact that a narrow beam will diverge faster with distance than a wide beam. If the beam width (diameter) is “a”, the divergence angle will be wavelength/a. Referring now to FIG. 10, the natural divergence of a typical laser diode in one axis is three times more than the orthogonal axis, creating an oval beam with a 3:1 divergence ratio. For a typical 405-410 nm laser diode and a typical collimating lens used in CD or DVD players, having a focal length of 3-4 mm, the cross section of the beam at the collimating lens 19 is about 1×3 mm. At a certain distance “L” the beam will become round by itself due to faster divergence in the narrow dimension. This distance is given by the formula L=3a²/wavelength. For a=1 mm and wavelength ˜400 nm, L=3×1²/0.0004 mm=7.5 meter. At this distance the oval beam cross section 25 will become a round cross section 26. It is actually desired for the spot to be somewhat oval with the narrow direction aligned with the scan direction, to partially cancel out the slight blur caused by the finite on time of the beam (known as “motion blur”). Rotating the laser diodes will rotate the spots on the photopolymer by the same amount, allowing further optimization in generating a round exposed spot.

The words “lens” and “scanner” in this disclosure should be understood to mean any equivalent device bending or deflecting light. For example, lenses can be replaced by curved mirrors.

For 3D printer requiring more power, multi-mode laser diode having larger emitters can be used instead of single mode diodes. An array based on multi-mode diodes is disclosed in U.S. Pat. No. 5,995,475, hereby incorporated by reference.

For 3D printers exposing the liquid photopolymer from the top layer there are several methods to speed up the levelling of the liquid layer after the build platform decended one layer. Most use a moving roller or a blade to level the liquid, a process taking 1-10 seconds. After surface is levelled exposure can start. Because of the fast exposure speed of the present invention, the exposure and levelling can be combined into a single pass. The scanned image of the array can follow right behind the levelling device and expose the freshly levelled area. To speed up process even more the array can be optimized for a narrow dimension in the scan direction by using elongated array. By the way of example, a 100×10 array can be constructed on a 4 mm pitch using 3.8 mm diameter diodes. Such an array only needs about 40 mm of overscanning either end of scan, and the image can be scanned on the photopolymer in synchronization with the motion of the levelling device.

With higher powers the current invention can be used in 3D printers operating by ablation of polymers or by fusing polymer powder. For example, C-mount multimode laser diodes operating at 800-810 nm are available with outputs of 2W for a 100 um emitter. An array of 1200 such diodes will produce 2400W, sufficient for high speed powder fusing. In a scanning system based on such diodes the apertures of all optical elements need to be larger and depth of focus is significantly less.

While the main application of the invention is in the field of 3D printing, it should be viewed as a general purpose photopolymer exposure system capable of high power, resolution and data rate. Such a can be used for the exposure of printing plates, and in particular flexographic printing plates. If a printing plate is placed under the scanner instead of the liquid polymer layer, it would b exposed in a similar manner. The desired resolution for such plates is about 10 um with a spot size of about 15 um, requring typically a higher degree of interleaving.

Another photopolymer covered material is Printed Circuit Boards (PCB), common in the electronics industry. Such PCBs require an even higher resolution than printing plates. Typical resolution is about 5 um with spot sizes of 10 um. An interleaving of about 100 times is needed if a typical PCB is to be scanned without moving it during scanning In direct exposure of PCBs, also known as Direct Imaging, speed is key. The high degree of parallelism in the present invention enables very high data rates.

1. A photopolymer exposure system comprising a two dimensional laser diode array, an optical system for imaging said array on the photopolymer and a scanner for scanning image of said array over the photopolymer.

2. An exposure system as in claim 1 wherein said scanner scans the whole area of the photopolymer without requiring movement of the photopolymer or the array during scanning, said scanning performed by interleaving a plurality of scans.

3. An exposure system as in claim 1 wherein said photopolymer is a liquid photopolymer in a 3D printer.

4. An exposure system as in claim 1 wherein said photopolymer is a printing plate.

5. An exposure system as in claim 1 wherein said photopolymer is a flexographic printing plate.

6. An exposure system as in claim 1 wherein said photopolymer is a coating on a printed circuit board.

7. A stereolithography based 3D printer comprising a two dimensional laser diode array, an optical system for imaging said array on a layer of liquid photopolymer and a scanner for scanning image of said array over the photopolymer using interleaved scanning

8. A stereolithography based 3D printer as in claim 7 further comprising a moving levelling device to level surface of said liquid photopolymer, motion of said levelling device syncronized to said scanning to allow levelling and exposure to be performed in one pass.

9. An imaging system as in claim 1 wherein said scanner is an oscillating mirror.

10. An imaging system as in claim 1 wherein said scanning is created by relative motion between a reduced image of the array and an imaging lens.

11. An imaging system as in claim 1 wherein said scanning is performed in an interleaved mode.

12. An imaging system as in claim 1 wherein said scanning is performed in a non-interleaved mode.

13. An imaging system as in claim 1 wherein said laser diode array operates at a wavelength of 400 nm to 410 nm.

14. An imaging system as in claim 1 wherein said laser diode array operates at a wavelength of 800 nm to 980 nm.

15. An imaging system as in claim 1 including an optical image shifting device inserted between said array and said photopolymer in order to shift the image on the photopolymer in a cross-scan direction, said shifting used to create interleaved scanning.

16. An imaging system as in claim 1 wherein said laser diode array comprises of multiple rows, the position each row offset from previous row in order to reduce the apparent laser diode spacing when scanning.

17. An imaging system as in claim 1 wherein said optical system includes additional lenses to increase the apparent distance from the to the two dimensional array.

18. An imaging system as in claim 1 wherein said scanned image of array comprises of oval spots, said spots oriented with the narrow dimension of said ovals aligned with the direction of the scanning.

19. A 3D printer based on fusing of a polymer powder comprising a two dimensional multi-mode laser diode array, an optical system for imaging said array on the powder and a scanner for scanning image of said array over the powder.
